(19) United States
(12) Patent Application Publication
(10) Pub. No.: US 2024/0080994 A1
(43) Pub. Date: Mar. 7, 2024

(54) METHODS OF REDUCING DEFECTS FROM PATTERN MISALIGNMENT

(71) Applicant: Samsung Electronics Co., Ltd., Suwon-si (KR)

(72) Inventors: Gun Lee, Suwon-si (KR); Junwoo Myung, Suwon-si (KR); Yuseon Heo, Suwon-si (KR)

(21) Appl. No.: 18/446,544

(22) Filed: Aug. 9, 2023

(30) Foreign Application Priority Data
Sep. 2, 2022 (KR) 10-2022-0111136

(51) Int. Cl. H05K 3/46; H05K 1/02; H05K 1/03; H05K 1/11; H05K 3/00

(52) U.S. Cl. CPC H05K 3/465; H05K 1/0296; H05K 1/0306; H05K 1/114; H05K 3/0023; H05K 3/4661; H05K 3/4679; H05K 2201/09563; H05K 2201/096

(57) ABSTRACT

In fabricating a wiring structure, a first wiring is formed on a substrate. First and second light sensitive insulation layers that are reactive to light of first and second wavelength ranges, respectively, are sequentially formed on the first wiring. First and second exposing processes are performed using the light of the first and second wavelength ranges, respectively, to form first and second exposed portions in the first and second light sensitive insulation layers, respectively. The first and second exposed portions are removed by a developing process to form a hole and an opening, respectively. The hole and the opening extend through the first and second light sensitive insulation layers, respectively, to be connected to one another. A conductive layer is formed in the hole and in the opening, and is planarized to form a first via and a second wiring in the hole and in the opening, respectively.

### CROSS-REFERENCE TO RELATED APPLICATION

This application claims priority under 35 U.S.C. § 119 to Korean Patent Application No. 10-2022-0111136 filed on Sep. 2, 2022, in the Korean Intellectual Property Office, the disclosure of which is hereby incorporated by reference in its entirety.

### FIELD

Example embodiments of the present disclosure relate to a method of forming a wiring structure.

### BACKGROUND

When a wiring structure including a via and a wiring is formed, a photolithography process for forming the via and a photolithography processes substantially the same as or similar to those for forming the wiring may be independently performed. Thus, misalignment may occur between the via and the wiring.

### SUMMARY

Example embodiments provide an enhanced method of forming a wiring structure.

According to example embodiments of the inventive concepts, in a method of forming a wiring structure, i) a first wiring may be formed on a substrate. ii) First and second light sensitive insulation layers may be sequentially formed or stacked on the substrate and on the first wiring, and the first and second light sensitive insulation layers may be reactive to light of different first and second wavelength ranges, respectively. iii) A first exposing process may be performed using the light of the first wavelength range to form a first exposed portion in the first light sensitive insulation layer. iv) A second exposing process may be performed using the light of the second wavelength range to form a second exposed portion in the second light sensitive insulation layer. v) The first and second exposed portions may be removed by performing a developing process on the first and second light sensitive insulation layers to form a hole and an opening, respectively. The hole may extend through the first light sensitive insulation layer to the first wiring, and the opening may extend through the second light sensitive insulation layer to the hole. vi) A conductive layer may be formed in the hole and in the opening to form a first via and a second wiring in the hole and the opening, respectively. In some embodiments, ii) to vi) may be performed to form a second via and a third wiring on the second wiring.

According to example embodiments of the inventive concepts, in a method of forming a wiring structure, a first wiring, a first light sensitive insulation layer and a second light sensitive insulation layer may be sequentially formed or stacked on a substrate. First and second exposing processes may be performed on the first and second light sensitive insulation layers to form first and second exposed portions in the first and second light sensitive insulation layers, respectively. The first and second exposed portions may be removed by performing a first developing process on the first and second light sensitive insulation layers to form a first hole and a first opening, respectively, extending through the first and second light sensitive insulation layers, respectively. The first hole and the first opening may be connected to one another. A first via and a second wiring may be formed in the first hole and the first opening, respectively. Third and fourth light sensitive insulation layers may be sequentially formed or stacked on the second wiring. Third and fourth exposing processes may be performed on the third and fourth light sensitive insulation layers to form third and fourth exposed portions in the third and fourth light sensitive insulation layers, respectively. The third and fourth exposed portions may be removed by performing a second developing process on the third and fourth light sensitive insulation layers to form a second hole and a second opening, respectively, extending through the third and fourth light sensitive insulation layers, respectively. The second hole and the second opening may be connected to one another. A second via and a third wiring may be formed in the second hole and the second opening, respectively.

According to example embodiments of the inventive concepts, in a method of forming a wiring structure, a first wiring may be formed on a substrate. First and second light sensitive insulation layers may be sequentially stacked on the substrate and on the first wiring, and the first and second light sensitive insulation layers may be reactive to light of different first and second wavelength ranges, respectively. First and second exposing processes may be performed on the first and second light sensitive insulation layers to form first and second exposed portions in the first and second light sensitive insulation layers, respectively. The first and second exposing processes may be performed using the light of the different first and second wavelength ranges, respectively. The first and second exposed portions may be removed by performing a first developing process on the first and second light sensitive insulation layers to form a first hole and a first opening, respectively, extending through the first and second light sensitive insulation layers, respectively. The first hole and the first opening may be connected to one another. A first plating process may be performed to form a first conductive layer in the first hole and in the first opening. The first conductive layer may be planarized to form a first via and a second wiring in the first hole and in the first opening, respectively. Third and fourth light sensitive insulation layers may be sequentially formed or stacked on the second wiring and the second light sensitive insulation layer, and the third and fourth light sensitive insulation layers may be reactive to light of different third and fourth wavelength ranges, respectively. Third and fourth exposing processes may be performed on the third and fourth light sensitive insulation layers to form third and fourth exposed portions in the third and fourth light sensitive insulation layers, respectively. The third and fourth exposing processes may be performed using the light of the different third and fourth wavelength ranges, respectively. The third and fourth exposed portions may be removed by performing a second developing process on the third and fourth light sensitive insulation layers to form a second hole and a second opening, respectively, extending through the third and fourth light sensitive insulation layers, respectively. The second hole and the second opening may be connected to one another. A second plating process may be performed to form a second conductive layer in the second hole and in the second opening. The second conductive layer may be planarized to form a second via and a third wiring in the second hole and in the second opening, respectively.

In the method of forming the wiring structure, light sensitive insulation layers having different reaction wavelength ranges may be stacked, and respective exposing processes may be performed using lights of different wavelength ranges with the same exposing equipment. Thus, the respective exposing processes may be performed using the same alignment key, so that misalignment may not occur.

Additionally, the hole and the opening may be simultaneously formed by one (e.g., a single) developing process, so that misalignment between the via and the wiring in the hole and the opening, which may occur due to the deformation of the light sensitive insulation layers during the developing process, may be reduced.

### BRIEF DESCRIPTION OF THE DRAWINGS

FIG. 1 is a flowchart illustrating a method of forming a wiring structure in accordance with example embodiments.

FIGS. 2, 3, 4, 5, 6, 7, 8, 9, 10, 11, 12, 13, and 14 are plan views and cross-sectional views illustrating the method of forming the wiring structure.

### DETAILED DESCRIPTION

The above and other aspects and features of the inventive concepts will become readily understood from detail descriptions that follow, with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts. The terms “comprises,” “comprising,” “includes” and/or “including,” when used herein, specify the presence of stated elements, but do not preclude the presence of additional elements. The term “and/or” includes any and all combinations of one or more of the associated listed items. When an element or layer is described as “directly on” another element or layer, no intervening elements or layers are present.

As described herein, two directions among horizontal directions substantially parallel to an upper surface of a substrate may be referred to as first and second directions D1 and D2, respectively, and a vertical direction substantially perpendicular to the upper surface of the substrate may be referred to as a third direction D3.

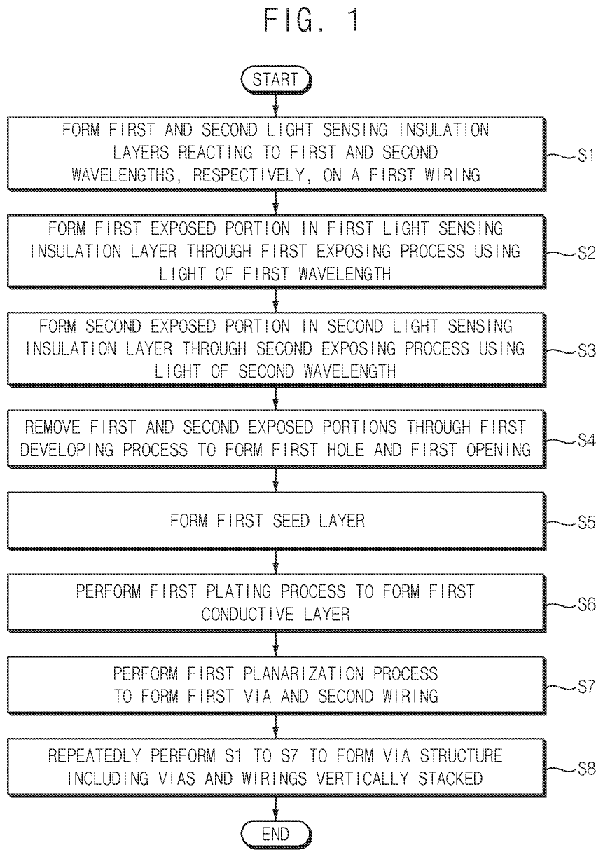

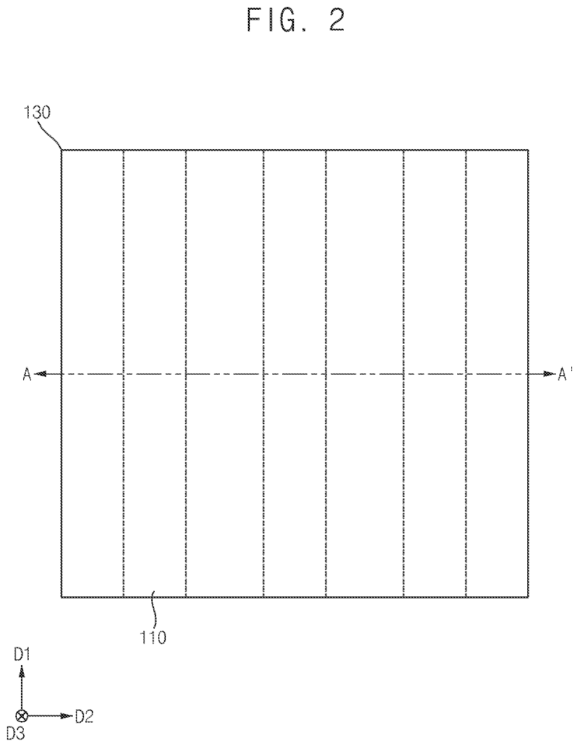

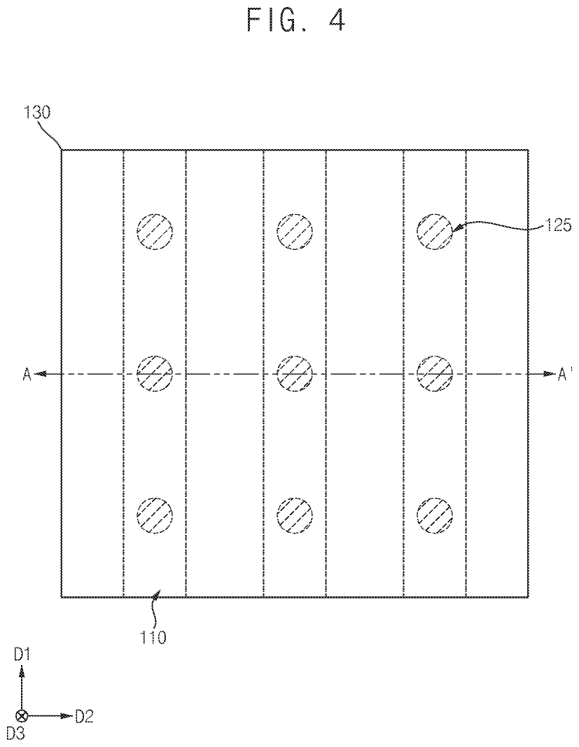

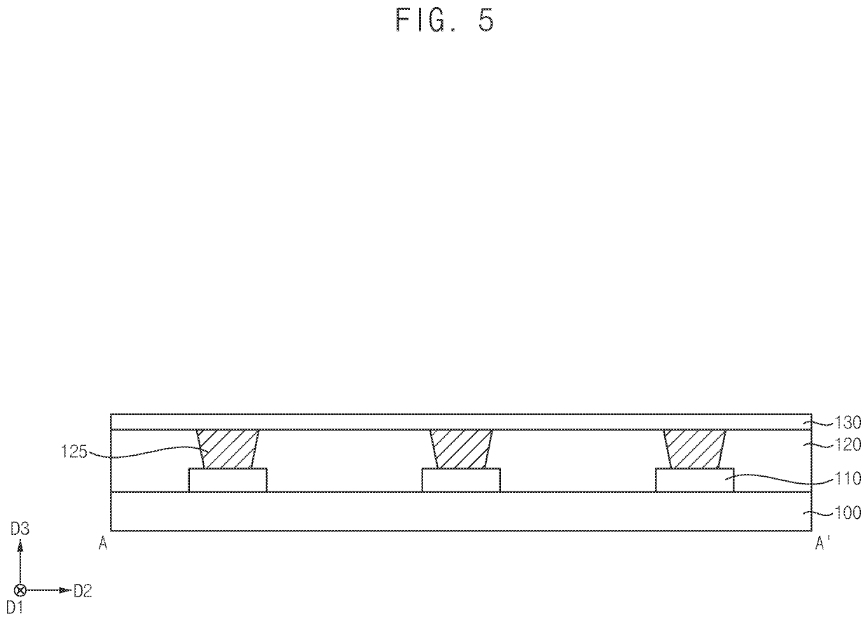

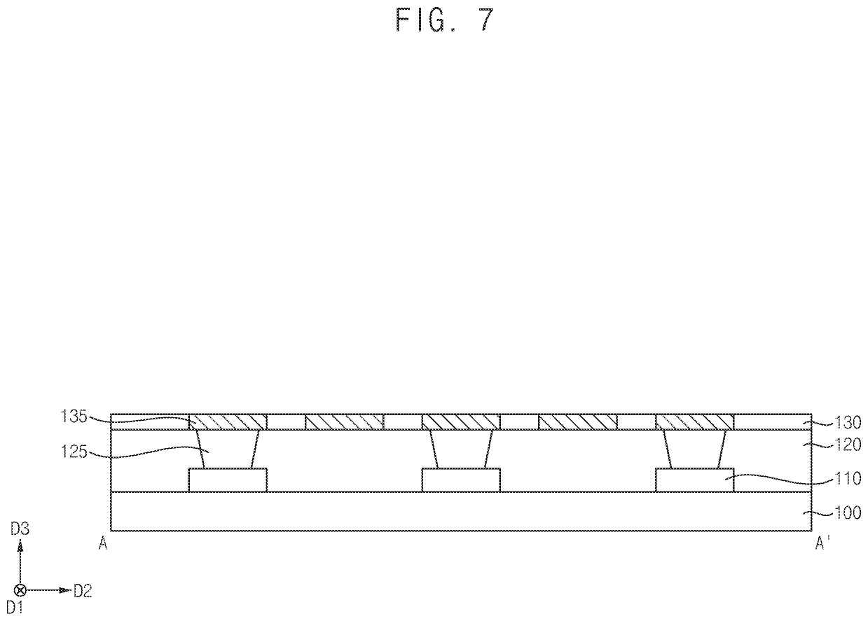

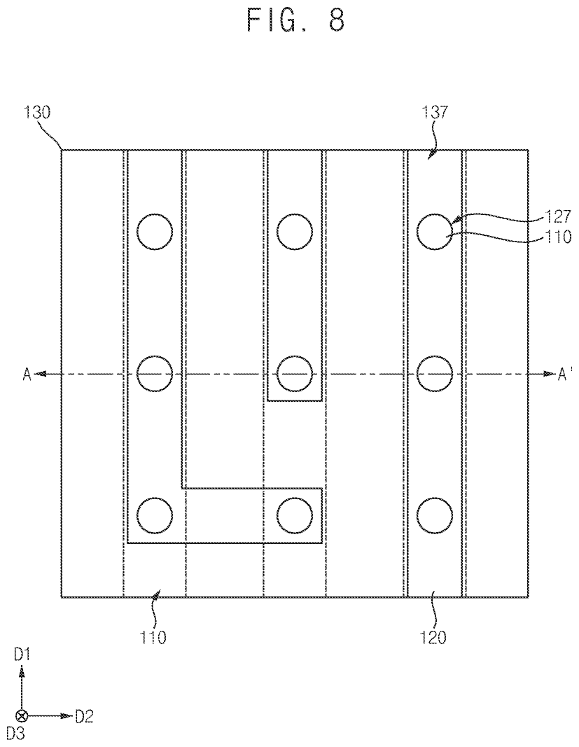

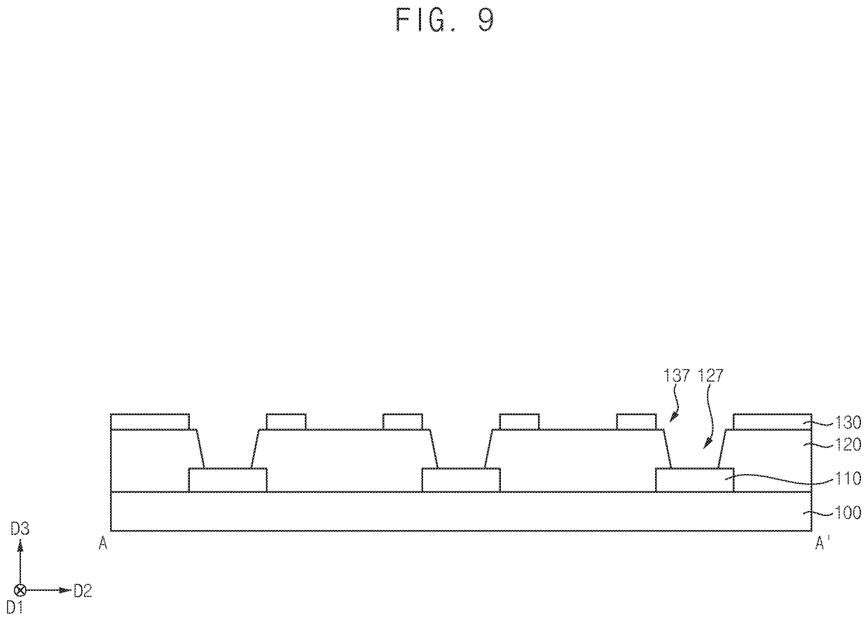

FIG. 1 is a flowchart illustrating a method of forming a wiring structure in accordance with example embodiments, and FIGS. 2 to 14 are plan views and cross-sectional views illustrating the method of forming the wiring structure.

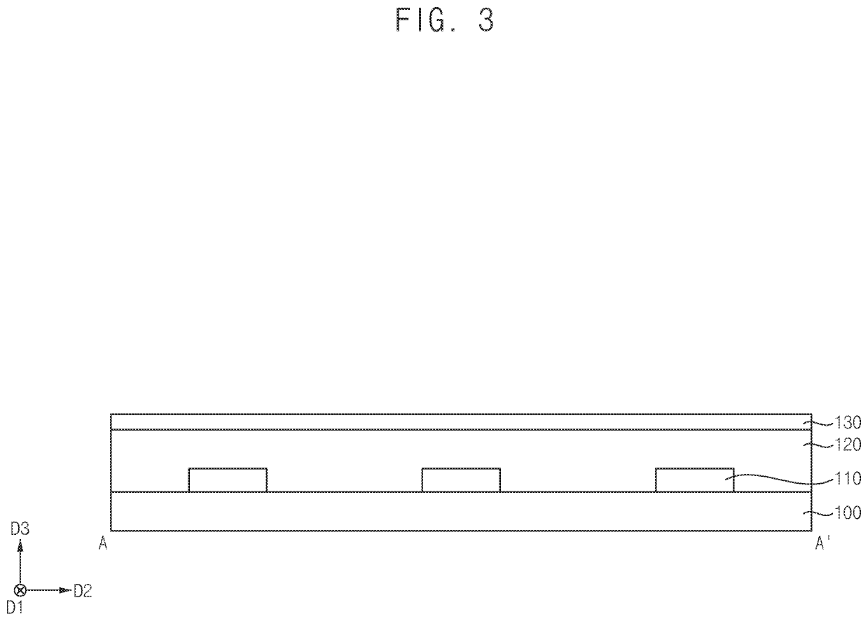

Particularly, FIGS. 2, 4, 6, 8 and 12 are the plan views, and FIGS. 3, 5, 7, 9-11 and 13-14 are cross-sectional views taken along lines A-A′ of corresponding plan views, respectively.

Referring to FIGS. 1 to 3, in step S1, a first wiring 110 may be formed on a substrate 100, a first light sensing insulation layer 120 may be formed on the substrate 100 to cover the first wiring 110, and a second light sensing insulation layer 130 may be formed on the first light sensing insulation layer 120. The light sensing insulation layers 120, 130 may also be referred to herein as “light sensitive” or photosensitive insulation layers.

The substrate 100 may include a semiconductor material, e.g., silicon, germanium, silicon-germanium, etc., or III-V group compounds, e.g., GaP, GaAs, GaSb, etc. In an example embodiment, the substrate 100 may be a silicon-on-insulator (SOI) substrate or a germanium-on-insulator (GOI) substrate.

For example, the first wiring 110 may extend in the first direction D1 on the substrate 100, and a plurality of first wirings 110 may be spaced apart from each other in the second direction D2. However, the inventive concept may not be limited thereto, and the first wirings 110 may have various layouts.

The first wiring 110 may include a conductive material, e.g., a metal, a metal nitride, a metal silicide, etc.

In example embodiments, each of the first and second light sensing insulation layers 120 and 130 may include a polymer resin, e.g., photo imageable dielectric (PID).

In example embodiments, the first and second light sensing or light sensitive insulation layers 120 and 130 may be reactive or configured to react (e.g., to change one or more material properties thereof) in response to light having different wavelengths, respectively. That is, a first wavelength range of light (to which the first light sensing insulation layer 120 may be photosensitive or may mainly react) and a second wavelength range of light (to which the second light sensing insulation layer 130 may be photosensitive or may mainly react) may be different from each other. The different first and second wavelength ranges may be overlapping, or may be non-overlapping.

For example, each of the first wavelength range and the second wavelength range may include one of a peak wavelength of 436 nm of a g-line, a peak wavelength of 405 nm of an h-line, and a peak wavelength of 365 nm of an i-line. In an example embodiment, the first wavelength range may include 365 nm and the second wavelength range may include 405 nm. However, embodiments described herein are not limited thereto.

Referring to FIGS. 1, 4 and 5, in step S2, a first exposing process may be performed so that a portion of the first light sensing insulation layer 120 may be converted into a first exposed portion 125.

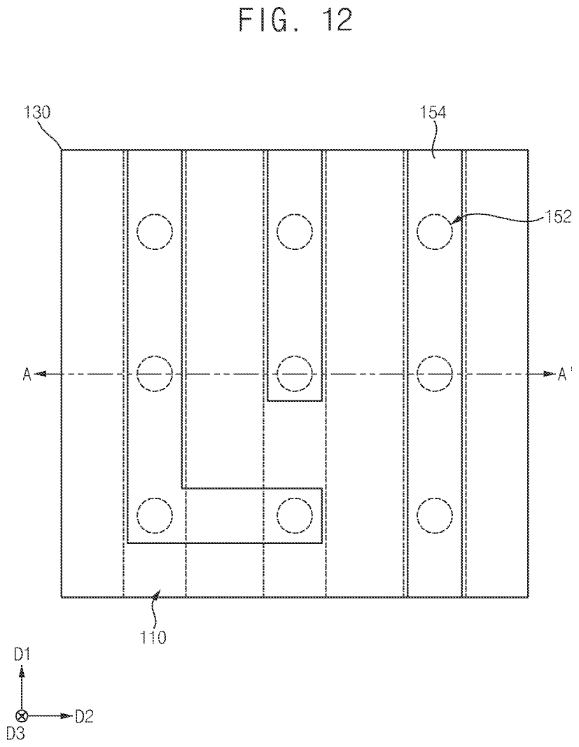

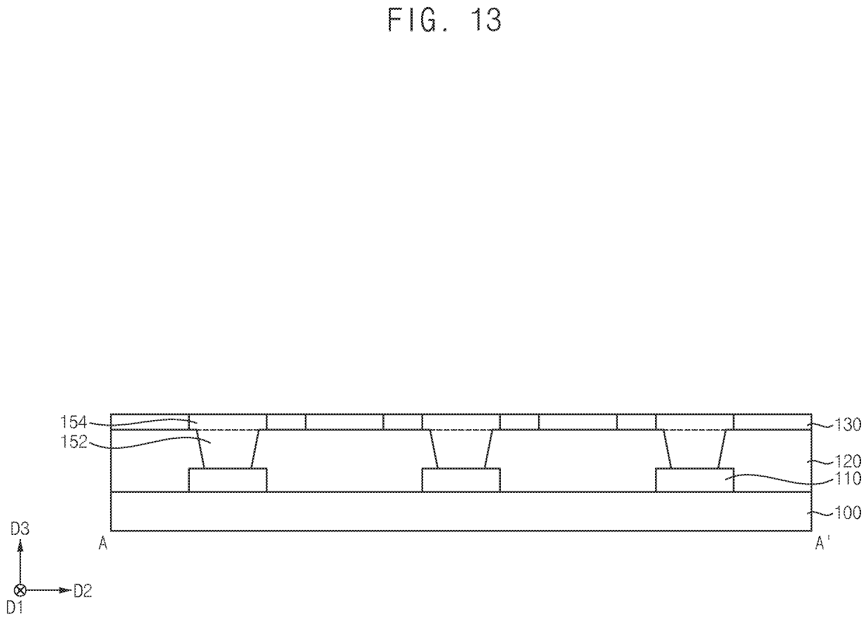

That is, a light or a laser may be emitted from a light source onto the first and second light sensing insulation layers 120 and 130 with a first photomask including a pattern having a shape of a first via 152 (refer to FIGS. 12 and 13) over the substrate 100 including the first and second light sensing insulation layers 120 and 130 thereon.

In an example embodiment, the light source may be a mercury lamp. Alternatively, the light source/drain may be an LED.

In example embodiments, the light source may emit a light having the first wavelength range to which the first light sensing insulation layer 120 may mainly react, and thus the second light sensing insulation layer 130 may not react to the light, while the first light sensing insulation layer 120 may react to the light to be cured.

If the light source is a mercury lamp, a light emitted from the mercury lamp may be filtered into one of a g-line, an h-line and an i-line, e.g., the i-line by using a first band-pass filter that may block or prevent passage of light of a given wavelength range.

In example embodiments, the first exposed portion 125 may be formed on each of the first wirings 110, and a plurality of first exposed portions 125 may be spaced apart from each other in the first direction D1. However, the inventive concept may not be limited thereto.

Referring to FIGS. 1, 6 and 7, in step S3, a second exposing process may be performed so that a portion of the second light sensing insulation layer 130 may be converted into a second exposed portion 135.

That is, a light or a laser may be emitted from the light source onto the first and second light sensing insulation layers 120 and 130 with a second photomask including a pattern having a shape of a second wiring 154 (refer to FIGS. 12 and 13) over the substrate 100 including the first and second light sensing insulation layers 120 and 130 thereon.

In example embodiments, the light source may emit a light having the second wavelength range to which the second light sensing insulation layer 130 may mainly react, and thus the first light sensing insulation layer 120 may not react to the light, while the second light sensing insulation layer 130 may react to the light to be cured.

If the light source is a mercury lamp, a light emitted from the mercury lamp may be filtered into one of a g-line, an h-line and an i-line, e.g., the h-line by using a second band-pass filter that may blocking a light of a given wavelength range.

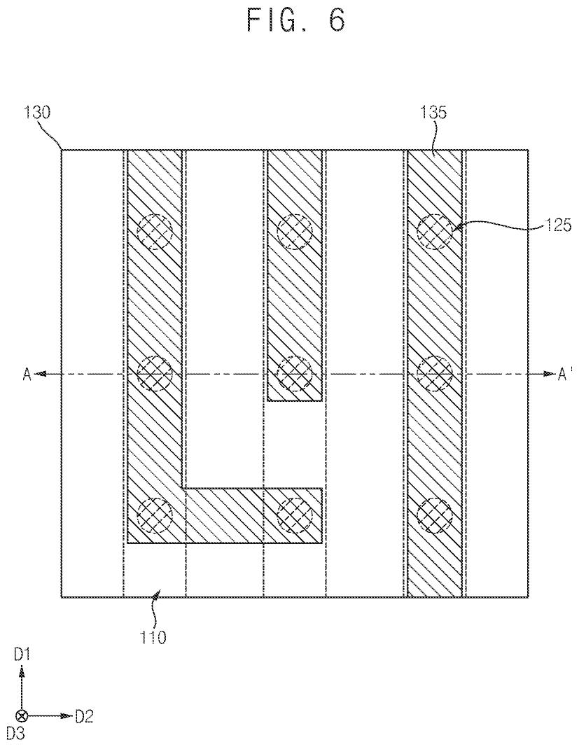

In example embodiments, the second exposed portion 135 may be formed on the first exposed portion 125, and may extend in the first direction D1 or in the second direction D2. FIG. 6 shows that the second exposed portion 135 extends in the first direction D1, or includes a first extension portion extending in the first direction D1 and a second extension portion extending in the second direction D2, however, the inventive concept may not be limited thereto.

Referring to FIGS. 1, 8 and 9, in step S4, a first developing process may be performed to remove the first and second exposed portions 125 and 135 included in the first and second light sensing insulation layers 120 and 130, respectively, and thus a first hole 127 and a first opening 137 may be formed.

That is, a developing solution may be spread on the first and second light sensing insulation layers 120 and 130 so that the first and second exposed portions 125 and 135 may be removed.

The first hole 127 that may be formed by the first developing process may partially expose an upper surface of the first wiring 110, and a plurality of first holes 127 may be spaced apart from each other in the first direction D1 on each of the first wirings 110. Additionally, the first opening 137 may be connected to the first hole 127, and may partially expose an upper surface of the first light sensing insulation layer 120. The first opening 137 may extend in the first direction D1 or in the second direction D2.

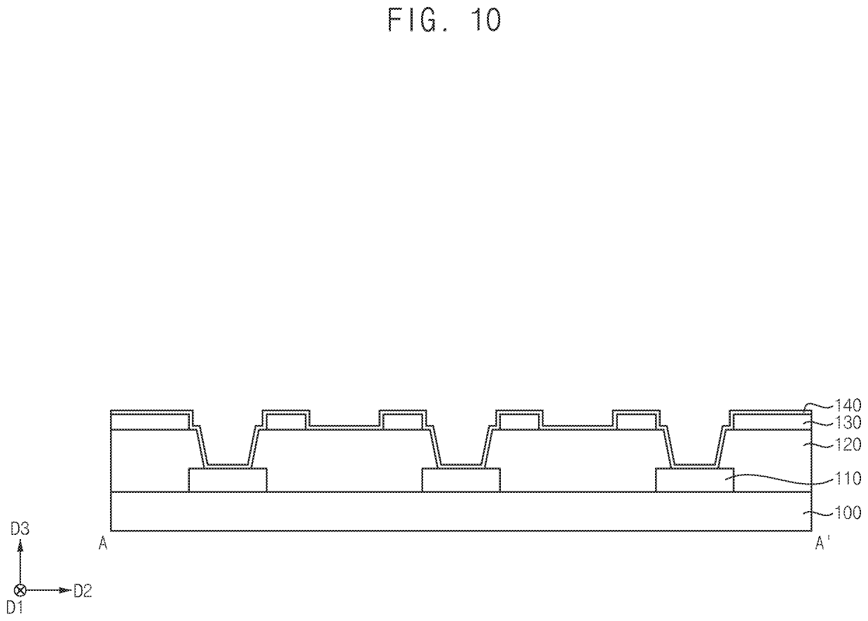

Referring to FIGS. 1 and 10, in step S5, a first seed layer 140 may be formed on the upper surface of the first wiring 110 exposed by the first hole 127, on sidewalls of the first hole 127 and the first opening 137, on the upper surface of the first light sensing insulation layer 120 exposed by the first opening 137, and on an upper surface of the second light sensing insulation layer 130 outside the first opening 137.

The first seed layer 140 may include a metal, e.g., copper, aluminum, etc.

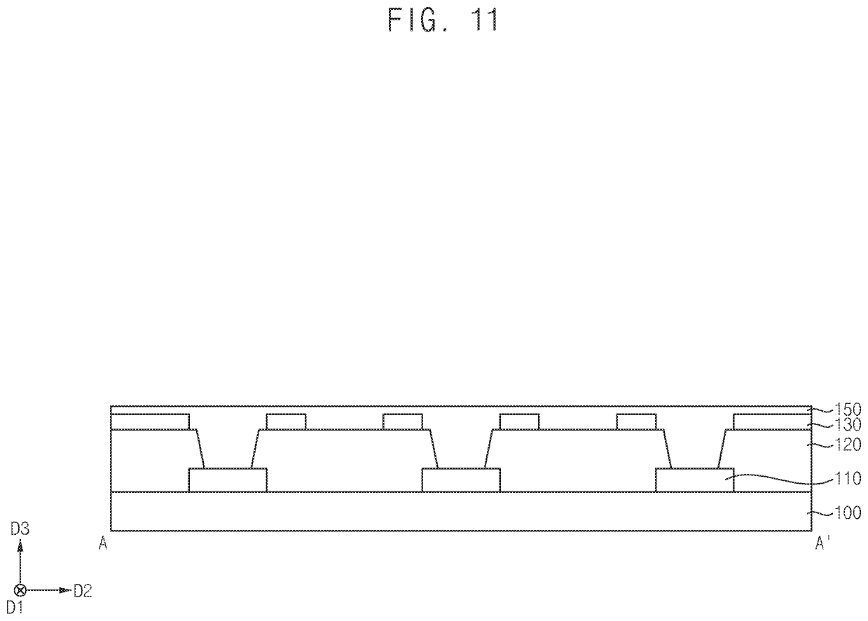

Referring to FIGS. 1 and 11, in step S6, a first plating process may be performed to form a first conductive layer 150 in the first hole 127 and the first opening 137.

In example embodiments, the first conductive layer 150 may fill the first hole 127 and the first opening 137, and may be further formed on the upper surface of the second light sensing insulation layer 130.

The first plating process may include, e.g., an electroplating process and an electroless plating process, and the first conductive layer 150 may include a metal, e.g., a copper, aluminum, etc.

Referring to FIGS. 1, 12 and 13, in step S7, a first planarization process may be performed on the first conductive layer 150.

In example embodiments, the first planarization process may include a chemical mechanical polishing (CMP) process, a grinding process, an etch back process, etc.

By the first planarization process, the first conductive layer 150 may be transformed into the first via 152 filling the first hole 127 and the second wiring 154 filling the first opening 137.

In example embodiments, the first via 152 may contact the upper surface of the first wiring 110, and a plurality of first vias 152 may be spaced apart from each other in the first direction D1 on each of the first wirings 110. The second wiring 154 may contact the first via 152, and may extend in the first direction D1 or in the second direction D2 on the first light sensing insulation layer 120.

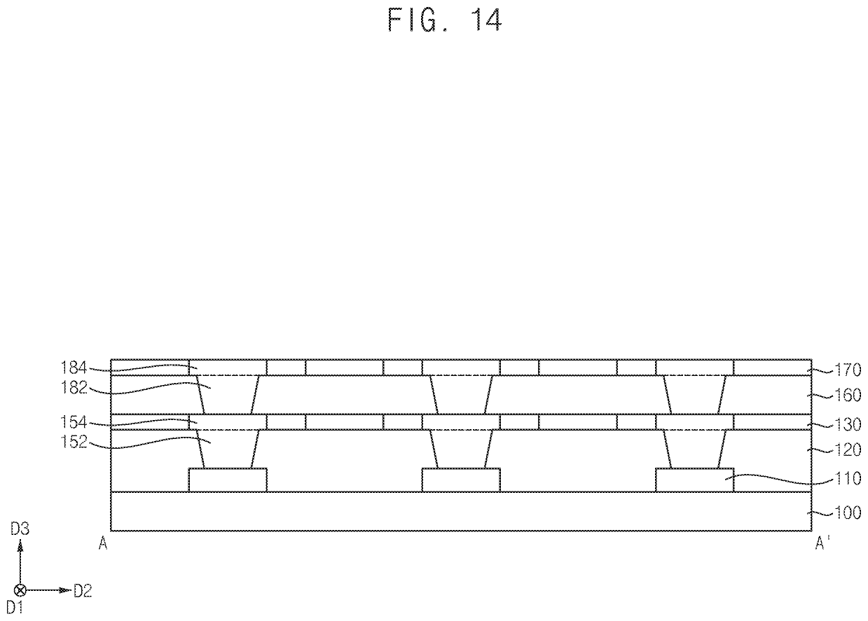

Referring to FIGS. 1 and 14, in step S8, steps S1 to S7 illustrated with reference to FIGS. 1 to 13 may be iteratively performed.

Thus, third and fourth light sensing insulation layers 160 and 170 may be sequentially stacked on the second light sensing insulation layer 130 and the second wiring 154, third and fourth exposing processes may be performed on the third and fourth light sensing insulation layers 160 and 170, respectively, and a second developing process may be performed on the third and fourth light sensing insulation layers 160 and 170, so that a second hole and a second opening may be formed through the third and fourth light sensing insulation layers 160 and 170, respectively, to be connected with each other. The second hole may expose the upper surface of the second wiring 154.

A second seed layer may be formed on the upper surface of the second wiring 154 exposed by the second hole, on sidewalls of the second hole and the second opening, and on an upper surface of the fourth light sensing insulation layer 170 outside the second opening, a second plating process may be performed on the second seed layer to form a second conductive layer, and a second planarization process may be performed on the second conductive layer to form a second via 182 and a third wiring 184 in the second hole and the second opening, respectively.

In example embodiments, the second via 182 may contact the upper surface of the second opening 154, and a plurality of second vias 182 may be spaced apart from each other in the first direction D1 or in the second direction D2. Additionally, the third wiring 184 may extend in the first direction D1 or in the second direction D2 to commonly contact upper surfaces of the second vias 182.

The wiring structure may be formed by the above processes.

As illustrated above, the first via 152 and the second wiring 154 may not be independently formed, but may be formed by the same photolithography process.

For example, if a light sensing insulation layer is formed, an exposing process and a developing process are performed on the light sensing insulation layer to form the first hole 127, a photoresist layer is formed, an exposing process and a developing process are performed on the photoresist layer to form the first opening 137, and the first via 152 and the second wiring 154 are formed in the first hole 127 and the first opening 137, respectively, the photolithography process including the exposing process and the developing process may be performed twice.

Thus, an alignment key for forming the first hole 127 and an alignment key for forming the first opening 137 are different from each other, so that the possibility or likelihood of misalignment between the photolithography processes may increase. Additionally, the light sensing insulation layer and/or the photoresist layer may be deformed during the developing process so that the alignment between the first via 152 and the second wiring 154 may be deteriorated.

However, in example embodiments, the first and second light sensitive insulation layers 120 and 130 that are reactive to different wavelength ranges from each other may be stacked, and the first and second exposing processes may be performed by the same exposing equipment but using light having the different wavelength ranges, so that the first and second exposing processes may be performed using the same alignment keys to prevent the misalignment between the first and second exposing processes.

Additionally, the first hole 127 and the first opening 137 may be simultaneously formed by one exposing process and/or during a same developing process, so that the misalignment between the first via 152 and the second wiring 154 that may occur due to the deformation of the first and second light sensing insulation layers 120 and 130 during the developing process may be reduced.

The photolithography process including the first and second exposing processes and the first developing process may be performed on the first wiring 110 to form the first hole 127 and the first opening 137, the first via 152 and the second wiring 154 may be formed in the first hole 127 and the first opening 137, respectively, the photolithography process including the third and fourth exposing processes and the second developing process may be performed on the second wiring 154 to form the second hole and the second opening, and the second via 182 and the third wiring 184 may be formed in the second hole and the second opening, respectively, however, the inventive concept may not be limited thereto.

For example, only one photolithography process may be performed to form a wiring structure including the first wiring 110, the first via 152 and the second wiring 154 sequentially stacked in the third direction D3, or photolithography processes may be performed more than twice to form a wiring structure including wirings and vias alternately and repeatedly stacked in the third direction D3.

While the present inventive concepts have been shown and described with reference to example embodiments thereof, it will be understood by those of ordinary skill in the art that various changes in form and details may be made thereto without departing from the scope of the present inventive concepts as set forth by the following claims.

What is claimed is:

1. A method of fabricating a wiring structure, the method comprising:
forming a first wiring on a substrate;
sequentially forming first and second light sensitive insulation layers on the substrate and on the first wiring, wherein the first and second light sensitive insulation layers are reactive to light of first and second wavelength ranges, respectively, and the first wavelength range is different from the second wavelength range;
performing a first exposing process using the light of the first wavelength range to form a first exposed portion in the first light sensitive insulation layer;
performing a second exposing process using the light of the second wavelength range to form a second exposed portion in the second light sensitive insulation layer;
removing the first and second exposed portions by performing a developing process on the first and second light sensitive insulation layers to form a hole and an opening, respectively, the hole extending through the first light sensitive insulation layer to the first wiring, and the opening extending through the second light sensitive insulation layer to the hole;
forming a conductive layer in the hole and in the opening to form a first via and a second wiring in the hole and in the opening, respectively.

2. The method according to claim 1, wherein each of the first and second wirings extends in a first direction or a second direction, the first direction being parallel to an upper surface of the substrate, and the second direction being parallel to the upper surface of the substrate and crossing the first direction, and
wherein the first via is one of a plurality of first vias spaced apart from each other in the first direction or in the second direction on the first wiring.

3. The method according to claim 1, wherein the sequentially forming, the first exposing process, the second exposing process, the removing, and the forming of the conductive layer are repeated to further form a second via and a third wiring on the second wiring,
wherein each of the second and third wirings extends in a first direction or a second direction, the first direction being parallel to an upper surface of the substrate, and the second direction being parallel to the upper surface of the substrate and crossing the first direction, and
wherein the second via is one of a plurality of second vias spaced apart from each other in the first direction or in the second direction on the first wiring.

4. The method according to claim 1, wherein the first and second exposing processes are performed by the same exposing equipment.

5. The method according to claim 4, wherein the first and second exposing processes are performed using a mercury lamp or an LED as a light source.

6. The method according to claim 5, wherein the first and second exposing processes are performed using the mercury lamp as a light source, the same exposing equipment includes a band-pass filter blocking a light of a given wavelength range, and
wherein the band-pass filter is configured to filter a light emitted from the mercury lamp into one of a g-line, an h-line, or an i-line.

7. The method according to claim 1, wherein the first and second exposing processes are performed using the same alignment key.

8. The method according to claim 1, wherein each of the first and second wavelength ranges includes one of 436 nm, 405 nm, or 365 nm.

9. The method according to claim 1, wherein forming the conductive layer comprises:
forming a seed layer on a surface of the first wiring that is exposed by the hole, on sidewalls of the hole and the opening, and on the second light sensitive insulation layer outside the opening; and
performing a plating process to form the conductive layer on the seed layer.

10. The method according to claim 1, wherein the sequentially forming the first and second light sensitive insulation layers, the first exposing process, the second exposing process, the removing the first and second exposed portions, and the forming of the conductive layer in the hole and in the opening are performed iteratively.

11. A method of fabricating a wiring structure, the method comprising:
sequentially forming a first wiring, a first light sensitive insulation layer and a second light sensitive insulation layer on a substrate;
performing first and second exposing processes on the first and second light sensitive insulation layers to form first and second exposed portions in the first and second light sensitive insulation layers, respectively;
removing the first and second exposed portions by performing a first developing process on the first and second light sensitive insulation layers to form a first hole and a first opening, respectively, extending through the first and second light sensitive insulation layers, respectively, the first hole and the first opening being connected to one another;
forming a first via and a second wiring in the first hole and in the first opening, respectively;
sequentially forming third and fourth light sensitive insulation layers on the second wiring;
performing third and fourth exposing processes on the third and fourth light sensitive insulation layers to form third and fourth exposed portions in the third and fourth light sensitive insulation layers, respectively;
removing the third and fourth exposed portions by performing a second developing process on the third and fourth light sensitive insulation layers to form a second hole and a second opening, respectively, extending through the third and fourth light sensitive insulation layers, respectively, the second hole and the second opening being connected to one another; and
forming a second via and a third wiring in the second hole and the second opening, respectively.

12. The method according to claim 11, wherein each of the first, second, and third wirings extends in a first direction or a second direction, the first direction being parallel to an upper surface of the substrate, and the second direction being parallel to the upper surface of the substrate and crossing the first direction, and
wherein the first via is one of a plurality of first vias spaced apart from each other in the first direction or in the second direction on the first wiring, and the second via is one of a plurality of second vias spaced apart from each other in the first direction or in the second direction on the second wiring.

13. The method according to claim 11, wherein the first and second light sensitive insulation layers are configured to be cured responsive to light of first and second wavelength ranges, respectively, wherein the first wavelength range is different from the second wavelength range, and
wherein the first and second exposing processes are performed using the light of the first and second wavelength ranges, respectively.

14. The method according to claim 13, wherein the third and fourth light sensitive insulation layers are configured to be cured responsive to light of third and fourth wavelength ranges, respectively, wherein the third wavelength range is different from the fourth wavelength range, and
wherein the third and fourth exposing processes are performed using the light of the third and fourth wavelength ranges, respectively.

15. The method according to claim 11, wherein the first and second exposing processes are performed by a same exposing equipment.

16. The method according to claim 11, wherein the first and second exposing processes are performed using a same alignment key.

17. The method according to claim 11, wherein the first hole partially exposes a surface of the first wiring, and
wherein forming the first via and the second wiring in the first hole and the first opening, respectively, comprises:
forming a first seed layer on the surface of the first wiring exposed by the first hole, on sidewalls of the first hole and the first opening, and on the second light sensitive insulation layer outside the first opening;
performing a plating process to form a first conductive layer on the first seed layer; and
planarizing the first conductive layer until the second light sensitive insulation layer is exposed.

18. The method according to claim 17, wherein the second hole partially exposes a surface of the second wiring, and
wherein forming the second via and the third wiring in the second hole and the second opening, respectively, comprises:
forming a second seed layer on the a surface of the second wiring exposed by the second hole, on sidewalls of the second hole and the second opening, and on the fourth light sensitive insulation layer outside the second opening;
performing a plating process to form a second conductive layer on the second seed layer; and
planarizing the second conductive layer until the fourth light sensitive insulation layer is exposed.

19. A method of fabricating a wiring structure, the method comprising:
forming a first wiring on a substrate;
sequentially forming first and second light sensitive insulation layers on the substrate and on the first wiring, wherein the first and second light sensitive insulation layers are reactive to light of different first and second wavelength ranges, respectively;
performing first and second exposing processes on the first and second light sensitive insulation layers to form first and second exposed portions in the first and second light sensitive insulation layers, respectively, the first and second exposing processes using the light of the different first and second wavelength ranges, respectively;
removing the first and second exposed portions by performing a first developing process on the first and second light sensitive insulation layers to form a first hole and a first opening, respectively, extending through the first and second light sensitive insulation layers, respectively, the first hole and the first opening being connected to one another;
performing a first plating process to form a first conductive layer in the first hole and in the first opening;
planarizing the first conductive layer to form a first via and a second wiring in the first hole and in the first opening, respectively;
sequentially forming third and fourth light sensitive insulation layers on the second wiring and on the second light sensitive insulation layer, the third and fourth light sensitive insulation layers are reactive to light of different third and fourth wavelength ranges, respectively;
performing third and fourth exposing processes on the third and fourth light sensitive insulation layers to form third and fourth exposed portions in the third and fourth light sensitive insulation layers, respectively, the third and fourth exposing processes using the light of the different third and fourth wavelength ranges, respectively;
removing the third and fourth exposed portions by performing a second developing process on the third and fourth light sensitive insulation layers to form a second hole and a second opening, respectively, extending through the third and fourth light sensitive insulation layers, respectively, the second hole and the second opening being connected to one another;
performing a second plating process to form a second conductive layer in the second hole and in the second opening; and
planarizing the second conductive layer to form a second via and a third wiring in the second hole and in the second opening, respectively.

20. The method according to claim 19, wherein each of the first, second, and third wirings extends in a first direction or a second direction, the first direction being parallel to an upper surface of the substrate, and the second direction being parallel to the upper surface of the substrate and crossing the first direction, and
wherein the first via is one of a plurality of first vias spaced apart from each other in the first direction or in the second direction on the first wiring, and the second via is one of a plurality of second vias spaced apart from each other in the first direction or in the second direction on the second wiring.
